(19) United States
(12) Patent Application Publication
(10) Pub. No.: US 2018/0076287 A1
(43) Pub. Date: Mar. 15, 2018

(54) SEMICONDUCTOR DEVICE AND SEMICONDUCTOR SUBSTRATE

(71) Applicant: KABUSHIKI KAISHA TOSHIBA, Tokyo (JP)

(72) Inventor: Tatsuya OHGURO, Yokohama (JP)

(73) Assignee: KABUSHIKI KAISHA TOSHIBA, Tokyo (JP)

(21) Appl. No.: 15/449,440

(22) Filed: Mar. 3, 2017

(30) Foreign Application Priority Data
Sep. 9, 2016 (JP) 2016-177020

(51) Int. Cl. H01L 29/10; H01L 29/20; H01L 29/205; H01L 29/778

(52) U.S. Cl. CPC H01L 29/1083; H01L 29/7787; H01L 29/205; H01L 29/2003

(57) ABSTRACT

A semiconductor device includes: a nitride semiconductor layer; a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer; a first electrode, the nitride semiconductor layer being located between the silicon substrate and the first electrode; and a second electrode that is spaced from the first electrode and located between the silicon substrate and the second electrode.

### CROSS-REFERENCE TO RELATED APPLICATION

This application claims the benefit of and priority to Japanese Patent Application No. 2016-177020, filed Sep. 9, 2016, the entire contents of which are incorporated herein by reference.

### FIELD

Embodiments described herein relate generally to a semiconductor device and a semiconductor substrate.

### BACKGROUND

Some semiconductor devices have a high breakdown voltage because they implement a particular nitride semiconductor layer. For example, a source electrode of a transistor formed on the nitride semiconductor layer can be grounded, and a voltage of several hundred volts can applied to a drain electrode of the transistor. A high voltage can be applied between the source electrode and the drain electrode. A breakdown voltage between the source electrode and the drain electrode can be made high by use of a nitride semiconductor layer having a high dielectric breakdown voltage.

The nitride semiconductor layer is formed on a silicon substrate, for example. In some implementations, the silicon substrate can be grounded, and a high voltage may be applied between the silicon substrate and the drain electrode of the transistor. Therefore, improvement of the breakdown voltage between the silicon substrate and the drain electrode is desirable in some implementations.

### SUMMARY

In some embodiments, according to one aspect, a semiconductor device includes: a nitride semiconductor layer; a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer; a first electrode, the nitride semiconductor layer being located between the silicon substrate and the first electrode; and a second electrode that is spaced from the first electrode, the nitride semiconductor layer being located between the silicon substrate and the second electrode.

In some embodiments, according to another aspect, a semiconductor substrate includes: a nitride semiconductor layer, and a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer.

In some embodiments, according to another aspect, a semiconductor device includes a nitride semiconductor layer, a silicon substrate including a p-type first region, an n-type second region provided between the first region and the nitride semiconductor layer, and a plurality of p-type third regions provided between the first region and the second region, each p-type third region in contact with the first region, a first electrode, and a second electrode spaced from the first electrode, wherein the nitride semiconductor layer is located between the silicon substrate and the first electrode, and the nitride semiconductor layer is located between the silicon substrate and the second electrode.

### BRIEF DESCRIPTION OF THE DRAWINGS

FIG. 1 is a schematic cross-sectional view of some embodiments of a semiconductor device according to a first aspect.

FIG. 2 is a schematic cross-sectional view of some embodiments of a step of a method of manufacturing the semiconductor device according to the first aspect.

FIG. 3 is a schematic cross-sectional view of some embodiments of a step of a method of manufacturing the semiconductor device according to the first aspect.

FIG. 4 is a schematic cross-sectional view of some embodiments of a step of a method of manufacturing the semiconductor device according to the first aspect.

FIG. 5 is a schematic cross-sectional view of embodiments of a comparative semiconductor device.

FIG. 6 is a schematic cross-sectional view of some embodiments of a semiconductor substrate according to a second aspect.

FIG. 7 is a schematic cross-sectional view of some embodiments of a semiconductor device according to a third aspect.

FIG. 8 is a schematic cross-sectional view of some embodiments of a step of a first example of a method of manufacturing a semiconductor device according to the third aspect.

FIG. 9 is a schematic cross-sectional view of some embodiments of a step of the first example method of manufacturing the semiconductor device according to the third aspect.

FIG. 10 is a schematic cross-sectional view of some embodiments of a step of the first example method of manufacturing the semiconductor device according to the third aspect.

FIG. 11 is a schematic cross-sectional view of some embodiments of a step of the first example method of manufacturing the semiconductor device according to the third aspect.

FIG. 12 is a schematic cross-sectional view of some embodiments of a step of the first example method of manufacturing the semiconductor device according to the third embodiment aspect.

FIG. 13 is a schematic cross-sectional view of some embodiments of a step of the first example method of manufacturing the semiconductor device according to the third aspect.

FIG. 14 is a schematic cross-sectional view of some embodiments of a step of the first example method of manufacturing the semiconductor device according to the third aspect.

FIG. 15 is a schematic cross-sectional view of some embodiments of a step of a second example method of manufacturing a semiconductor device according to the third aspect.

FIG. 16 is a schematic cross-sectional view of some embodiments of a step of the second example method of manufacturing the semiconductor device according to the third aspect.

FIG. 17 is a schematic cross-sectional view of some embodiments of a step of the second example method of manufacturing the semiconductor device according to the ¥ third aspect.

FIG. 18 is a schematic cross-sectional view of some embodiments of a step of the second example method of manufacturing the semiconductor device according to the third aspect.

FIG. 19 is a schematic cross-sectional view of some embodiments of a step of the second example method of manufacturing the semiconductor device according to the third aspect.

FIG. 20 is a schematic cross-sectional view of some embodiments of a step of the second example manufacturing process of the semiconductor device according to the third aspect.

### DETAILED DESCRIPTION

Some embodiments provide for a semiconductor device and a semiconductor substrate which are capable of improving a breakdown voltage between a silicon substrate and an electrode.

In general, according to some embodiments, a semiconductor device includes: a nitride semiconductor layer; a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer; a first electrode, the nitride semiconductor layer being located between the silicon substrate and the first electrode; and a second electrode that is spaced from the first electrode, the nitride semiconductor layer being located between the silicon substrate and the second electrode.

In the following description, corresponding devices, components and the like referred to by same reference signs may be described only once, without redundant repetition.

In the following description, the term “undoped” refers to an impurity concentration is not more than about 1×10¹⁵ centimeters (cm)³.

In the following description, an upward direction as shown in the drawings is referred to as “up” and a downward direction as shown in the drawing is referred to as “down” in order to indicate a positional relation of components and the like. In the following description, of the terms “up” and “down” do not necessarily indicate a relation with a direction of gravity.

### First Aspect

Some embodiments of a semiconductor device according to the first aspect include: a nitride semiconductor layer; a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer; a first electrode, the nitride semiconductor layer being located between the silicon substrate and the first electrode; and a second electrode that is spaced from the first electrode, the nitride semiconductor layer being located between the silicon substrate and the second electrode.

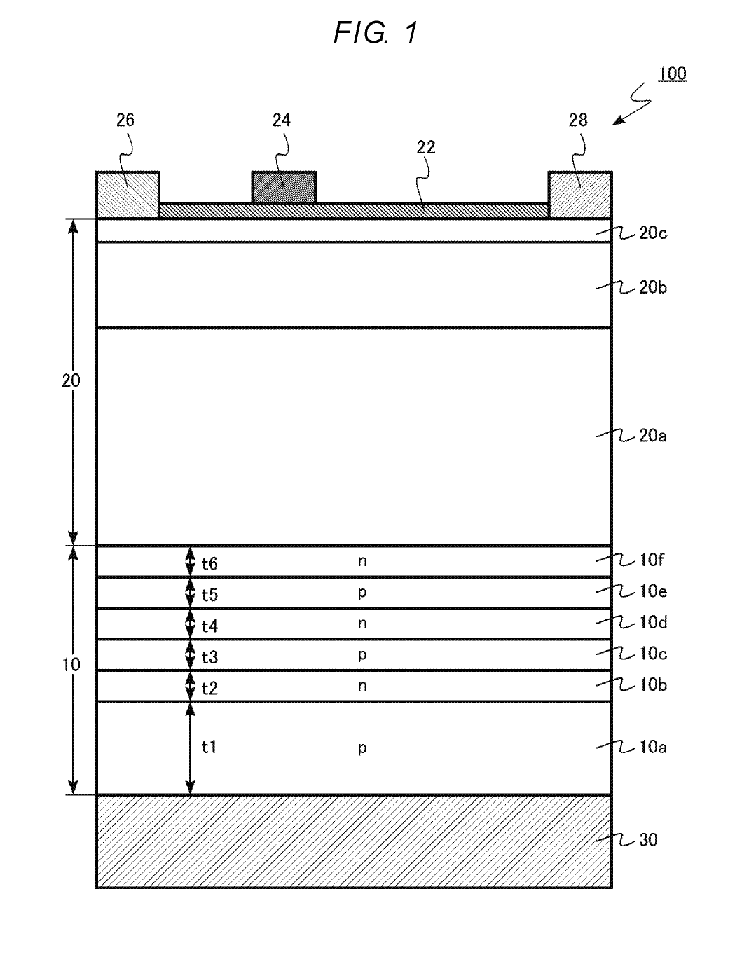

FIG. 1 is a schematic cross-sectional view of some embodiments of a semiconductor device according to the first aspect. The semiconductor device is a high-electron-mobility transistor (HEMT) using III-V compound semiconductors.

As illustrated in FIG. 1, an HEMT 100 semiconductor device includes a silicon substrate 10, a nitride semiconductor layer 20, a gate insulation layer 22, a gate electrode 24, a source electrode (first electrode) 26, a drain electrode (second electrode) 28, and a metal plate 30.

The metal plate 30 is, for example, a lead frame or a bed. The metal plate 30 includes nickel iron alloy 42, for example.

The silicon substrate 10 includes silicon whose surface has a plane orientation of (111). The silicon substrate 10 is bonded onto the metal plate 30. The silicon substrate 10 is bonded onto the metal plate 30, for example, using solder. The silicon substrate 10 has a thickness of about 100 micrometers (μm) or greater and about 300 μm or less, for example.

The silicon substrate 10 includes a p-type first region 10a, an n-type second region 10b, a p-type third region 10c, an n-type fourth region 10d, a p-type fifth region 10e, and an n-type sixth region 10f. A p-type region and an n-type region are alternately formed in the silicon substrate 10 (e.g. the p-type regions 10a, 10c, and 10e are alternately disposed with the n-type regions 10b, 10d and 10f). Five pn junctions are provided in the silicon substrate 10 (e.g. between the alternately disposed regions 10a through 10f).

Each of the p-type first region 10a, the n-type second region 10b, the p-type third region 10c, the n-type fourth region 10d, the p-type fifth region 10e, and the n-type sixth region 10f has a thickness of about 0.5 μm or greater and about 2.0 μm or less, for example.

For example, the thickness (t1 in FIG. 1) of the p-type first region 10a is thicker than the thickness (any of t2 to t6) of any of the n-type second region 10b, the p-type third region 10c, the n-type fourth region 10d, the p-type fifth region 10e, and the n-type sixth region 10f.

Each of the p-type first region 10a, the p-type third region 10c, and the p-type fifth region 10e has a p-type impurity concentration of not less than about 1×10¹⁴ atoms/cm³ and not more than about 1×10¹⁷ atoms/cm³, for example. For example, the p-type first region 10a has a p-type impurity concentration higher than that of each of the p-type third region 10c and the p-type fifth region 10e.

The n-type second region 10b, the n-type fourth region 10d, and the n-type sixth region 10f each have an n-type impurity concentration of not less than about 1×10¹⁴ atoms/cm³ and not more than about 1×10¹⁷ atoms/cm³, for example.

Defining the p-type impurity concentration of the p-type third region 10c as N3, defining the thickness of the p-type third region 10c as t3, defining the n-type impurity concentration of the n-type fourth region 10d as N4, and defining the thickness of the n-type fourth region 10d as t4, the following relation is satisfied for the HEMT 100: 0.8≦(N4×t4)/(N3×t3)≦1.2.

Defining the p-type impurity concentration of the p-type fifth region 10e as N5, defining the thickness of the p-type fifth region 10e as t5, defining the n-type impurity concentration of the n-type sixth region 10f as N6, and defining the thickness of the n-type sixth region 10f as t6, the following relation is satisfied for the HEMT 100: 0.8≦(N6×t6)/(N5×t5)≦1.2.

The p-type impurity concentration and the n-type impurity concentration in the silicon substrate 10 can be measured using, for example, SIMS (Secondary Ion Mass Spectrometry). The p-type impurity concentration and the n-type impurity concentration can be obtained using a value of a central portion in each of impurity regions, for example. In addition, the thickness of the p-type region and the n-type region in the silicon substrate 10 can be measured using, for example, SIMS or Scanning Capacitance Microscopy(SCM).

The silicon substrate 10 and the metal plate 30 are electrically connected to each other. For example, the silicon substrate 10 is grounded via the metal plate 30. In other words, a ground potential is applied to the silicon substrate 10 via the metal plate 30.

In some embodiments, the p-type first region 10a is grounded. However, the n-type second region 10b, the p-type third region 10c, the n-type fourth region 10d, the p-type fifth region 10e, and the n-type sixth region 10f may be in a floating state in which a potential is not fixed.

The pn junctions can exist in a space between the p-type first region 10a and the n-type second region 10b, the n-type second region 10b and the p-type third region 10c, the p-type third region 10c and the n-type fourth region 10d, the n-type fourth region 10d and the p-type fifth region 10e, and p-type fifth region 10e and the n-type sixth region 10f. Further, all of the n-type second region 10b, the p-type third region 10c, the n-type fourth region 10d, the p-type fifth region 10e, and the n-type sixth region 10f are not electrically or physically connected to any of the gate electrode 24, the source electrode 26, and the drain electrode 28. Accordingly, the n-type second region 10b, the p-type third region 10c, the n-type fourth region 10d, the p-type fifth region 10e, and the n-type sixth region 10f are in a floating state.

The nitride semiconductor layer 20 is provided on the silicon substrate 10. The nitride semiconductor layer 20 includes a buffer layer 20a, a channel layer 20b, and a barrier layer 20c. The nitride semiconductor layer 20 has a thickness of about 2 μm or greater and about 10 μm or less, for example.

The buffer layer 20a is provided on the silicon substrate 10. The buffer layer 20a can allow for relaxing and/or lessening lattice mismatch between the silicon substrate 10 and the channel layer 20b. In addition, the buffer layer 20a can allow for improving a breakdown voltage between the silicon substrate 10 and the drain electrode 28. The buffer layer 20a includes, for example, gallium nitride or aluminum gallium nitride.

The channel layer 20b is provided on the buffer layer 20a. The channel layer 20b is also referred to as an electron transit layer.

The channel layer 20b includes undoped Al_{X}Ga_{1-X}N (0≦X<1), for example. The channel layer 20b includes undoped gallium nitride (GaN), for example. The channel layer 20b has a thickness of about 0.2 μm or greater and about 2 μm or less, for example.

The barrier layer 20c is provided on the channel layer 20b. The barrier layer 20c is also referred to as an electron supply layer. The barrier layer 20c has an electron affinity smaller than that of the channel layer 20b. Since the electron affinity of the barrier layer 20c is smaller than that of the channel layer 20b, a two-dimensional electron gas (2-DEG) may be formed in the channel layer 20b. The barrier layer 20c has a bandgap larger than that of the channel layer 20b.

The barrier layer 20c includes undoped Al_{Y}Ga_{1-Y}N (0<Y≦1, X<Y), for example. The barrier layer 20c includes undoped aluminum gallium nitride, for example. The barrier layer 20c includes undoped Al_{0.2}Ga_{0.8}N, for example. The thickness of the barrier layer 20c is, for example, about 2 nanometers (nm) or greater and about 50 nm or less.

A heterojunction interface is formed between the channel layer 20b and the barrier layer 20c. A 2-DEG is formed in the channel layer 20b by a polarization charge of the heterojunction interface. The 2-DEG has high electron mobility, and can allow low on-resistance and high-speed switching during device operation.

The gate insulation layer 22 is provided on the barrier layer 20c. The gate insulation layer 22 is in contact with the barrier layer 20c.

The gate insulation layer 22 includes silicon nitride, for example. The gate insulation layer 22 has a thickness of about 4 nm or greater and about 20 nm or less, for example.

The gate electrode 24 is provided on the gate insulation layer 22. The gate electrode 24 is provided between the source electrode 26 and the drain electrode 28. For example, the gate electrode 24 is a metal electrode.

The source electrode 26 and the drain electrode 28 are provided on the barrier layer 20c. Each of the source electrode 26 and the drain electrode 28 is a metal electrode, for example.

For example, the source electrode 26 and the drain electrode 28 are in contact with the barrier layer 20c. The source electrode 26 and the drain electrode 28 are in contact with the barrier layer 20c by ohmic contact, for example. The source electrode 26 and the drain electrode 28 are electrically connected to the channel layer 20b via the barrier layer 20c.

The HEMT 100 includes a passivation layer (not illustrated) and the like disposed on the gate insulation layer 22 and the gate electrode 24.

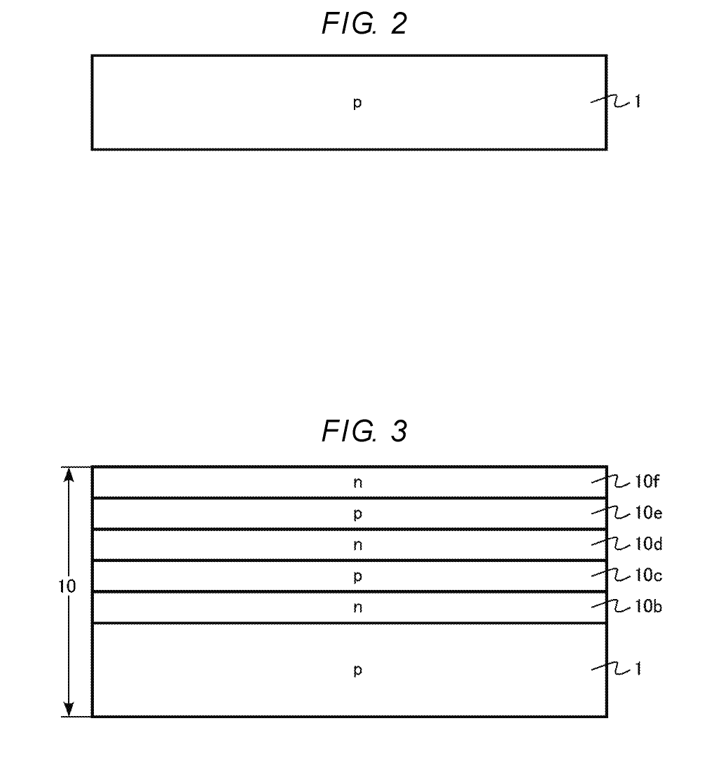

Some embodiments of a method of manufacturing the semiconductor device according to the first aspect will be described below. FIGS. 2 to 4 are schematic cross-sectional views of some steps of a method of manufacturing the semiconductor device according to the first aspect.

First, a p-type silicon substrate 1 is prepared whose surface has a plane orientation of (111) (see FIG. 2). The p-type silicon substrate 1 later becomes the p-type first region 10a.

Next, the n-type second region 10b, the p-type third region 10c, the n-type fourth region 10d, the p-type fifth region 10e, and the n-type sixth region 10f are formed in this order on the silicon substrate 1 through epitaxial growth (see FIG. 3).

The n-type second region 10b, the p-type third region 10c, the n-type fourth region 10d, the p-type fifth region 10e, and the n-type sixth region 10f can additionally or alternatively be formed by formation of a silicon layer having a low impurity concentration and ion implantation of impurities.

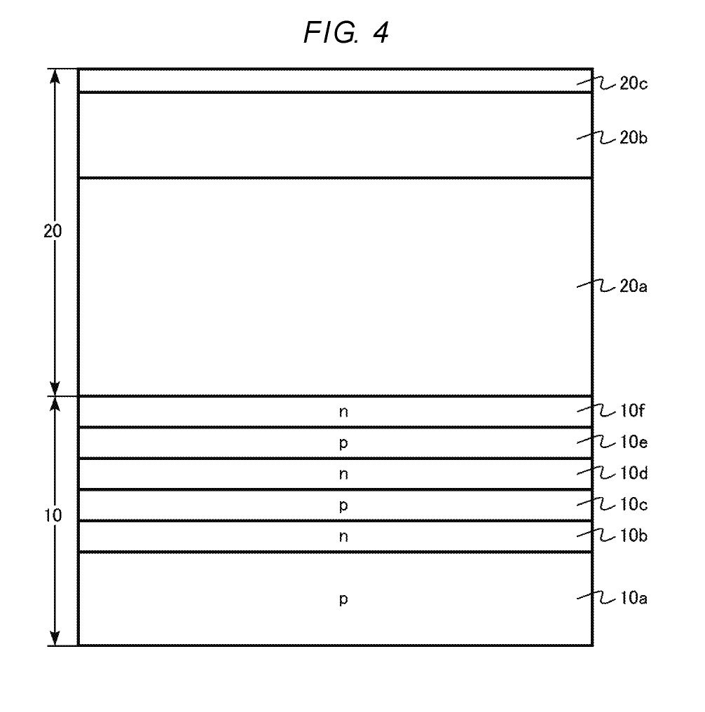

Next, for example, the buffer layer 20a, the channel layer 20b, the barrier layer 20c are grown on the n-type sixth region 10f through epitaxial growth (see FIG. 4). The buffer layer 20a, the channel layer 20b, and the barrier layer 20c are grown by metal organic chemical vapor deposition (MOCVD), for example.

Thereafter, the gate insulation layer 22, the gate electrode 24, the source electrode 26, the drain electrode 28, the passivation layer (not illustrated), and the like are formed by any appropriate process.

Then, the silicon substrate 10 and the nitride semiconductor layer 20 are bonded onto the metal plate 30 by solder, whereby, the manufacture HEMT 100 as illustrated in FIG. 1 may be completed.

Some manners of operation and/or advantages of the semiconductor device according to the first aspect will be described below.

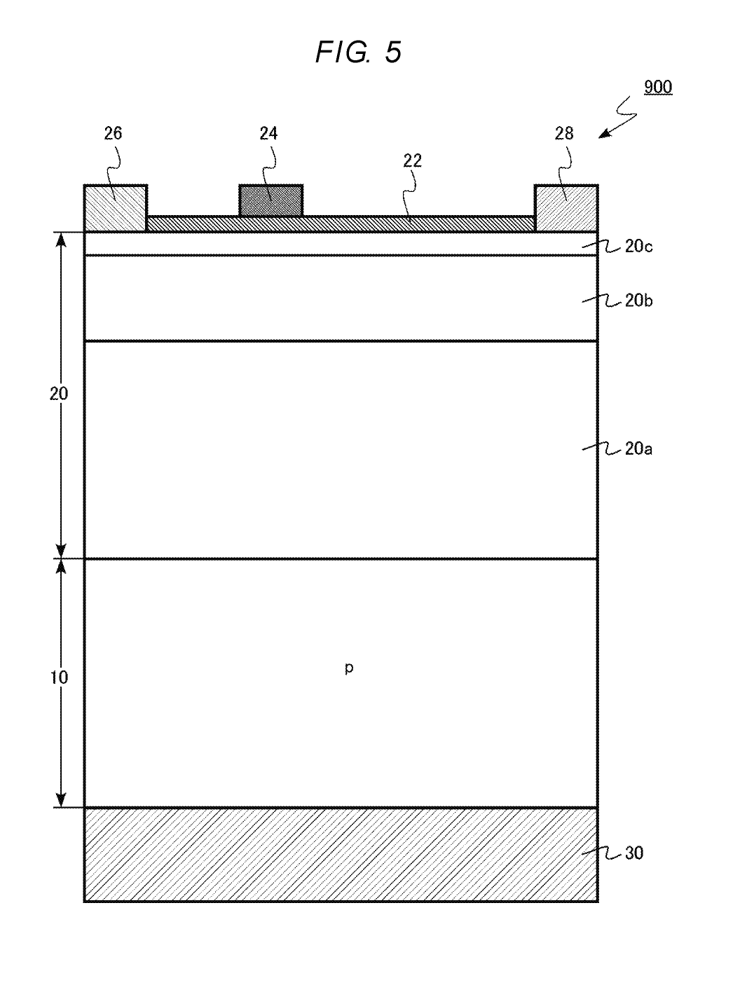

FIG. 5 is a schematic cross-sectional view of some embodiments of an HEMT 900 according to a comparative example. The HEMT 900 according to the comparative example includes a p-type silicon substrate 10 with no pn junction therein.

In an off state of the HEMT 900, a high voltage is applied between the silicon substrate 10 and the drain electrode 28 when the metal plate 30 is grounded. For example, assuming that the drain voltage is 450 V, a voltage of 450 V is applied between the silicon substrate 10 and the drain electrode 28.

When a high voltage is applied between the silicon substrate 10 and the drain electrode 28, a leak current may increase between the silicon substrate 10 and the drain electrode 28, resulting in possible malfunction of the HEMT. In addition, dielectric breakdown may occur between the silicon substrate 10 and the drain electrode 28, and thus the HEMT may be destroyed. Therefore, it is desirable in some implementations to improve the breakdown voltage between the silicon substrate 10 and the drain electrode 28.

In the following description, both of reduction in the leak current between the silicon substrate 10 and the drain electrode 28 and suppression of the dielectric breakdown between the silicon substrate 10 and the drain electrode 28 are taken to constitute improvements of the breakdown voltage between the silicon substrate 10 and the drain electrode 28.

For example, in order to improve the breakdown voltage between the silicon substrate 10 and the drain electrode 28, there is a method of using a high resistance substrate having a low impurity concentration as the silicon substrate 10 of the HEMT 900. Electric field strength between the silicon substrate 10 and the drain electrode 28 is relaxed by a depletion layer extending in the high resistance substrate, and the breakdown voltage between the silicon substrate 10 and the drain electrode 28 is improved.

However, there is a limit to increase the resistance of the silicon substrate 10. For example, even when the concentration of an impurity used as dopant is reduced, oxygen to be dissolved can be converted into an impurity donor by heat treatment at about 400° C. during the manufacturing of the HEMT, and thus the resistance is lowered. Furthermore, when the amount of oxygen to be dissolved is reduced, a slit may be formed in the silicon substrate by heat treatment at 700° C. or higher during the manufacturing of the HEMT.

In order to improve the breakdown voltage between the silicon substrate 10 and the drain electrode 28, the silicon substrate 10 may be set to a floating state rather than being grounded. However, since the potential of the silicon substrate 10 is fixed by capacitive coupling, the improvement of the breakdown voltage due to setting the silicon substrate 10 to a floating state is small.

In the HEMT 100 according to the first aspect, the silicon substrate 10 has a structure in which the p-type region and the n-type region are alternately stacked. In other words, a plurality of pn junctions are provided in the silicon substrate 10.

When a high voltage is applied between the silicon substrate 10 and the drain electrode 28, a depletion layer spreads into the p-type region and the n-type region, between which the pn junction is sandwiched, in the silicon substrate 10. For this reason, the electric field strength between the silicon substrate 10 and the drain electrode 28 is relaxed, and the breakdown voltage between the silicon substrate 10 and the drain electrode 28 is improved.

From the viewpoint of facilitating the spreading of the depletion layer into the p-type region and the n-type region and relaxing the electric field strength, it is desirable that the impurity concentration of the p-type region and the n-type region be low. Accordingly, the p-type impurity concentration of each of the p-type first region 10a, the p-type third region 10c, and the p-type fifth region 10e is desirably not more than about 1×10¹⁷ atoms/cm³, for example, and more desirably not more than about 1×10¹⁶ atoms/cm³. In addition, the n-type impurity concentration of each of the n-type second region 10b, the n-type fourth region 10d, and the n-type sixth region 10f is desirably not more than about 1×10¹⁷ atoms/cm³, for example, and more desirably not more than about 1×10¹⁶ atoms/cm³.

From the viewpoint of increasing the improvement effect of the breakdown voltage by the stacked structure of the p-type region and the n-type region, it is desirable that the amount of acceptors contained in the p-type region be substantially equal to the amount of donors contained in the n-type region, the pn junction being sandwiched between the p-type region and the n-type region. Accordingly, defining the p-type impurity concentration of the p-type third region 10c as N3, defining the thickness of the p-type third region 10c as t3, defining the n-type impurity concentration of the n-type fourth region 10d as N4, and defining the thickness of the n-type fourth region 10d as t4, the following relation is desirably satisfied: 0.8≦(N4×t4)/(N3×t3)≦1.2. Similarly, defining the p-type impurity concentration of the p-type fifth region 10e as N5, defining the thickness of the p-type fifth region 10e as t5, defining the n-type impurity concentration of the n-type sixth region 10f as N6, and defining the thickness of the n-type sixth region 10f as t6, the following relation is desirably satisfied: 0.8≦(N6×t6)/(N5×t5)≦1.2.

From the viewpoint of preventing damage caused during a lapping process of the rear surface of the silicon substrate 10 from affecting the pn junction provided in the silicon substrate 10, it is desirable that the thickness (t1 in FIG. 1) of the p-type first region 10a be sufficiently thick. Therefore, the thickness of the p-type first region 10a is desirably thicker than the thickness (any of t2 to t6) of any of the n-type second region 10b, the p-type third region 10c, the n-type fourth region 10d, the p-type fifth region 10e, and the n-type sixth region 10f.

From the viewpoint of reducing the contact resistance between the silicon substrate 10 and the metal plate 30, it is desirable that the p-type impurity concentration of the p-type first region 10a be high. In addition, from the viewpoint of causing the p-type first region 10a to function as a field plate and improving current collapse characteristics of the HEMT 100, it is desirable that the p-type impurity concentration of the p-type first region 10a is high.

Accordingly, it is desirable that the p-type impurity concentration of the p-type first region 10a be higher than the p-type impurity concentration of each of the p-type third region 10c and the p-type fifth region 10e. For example, the p-type impurity concentration of the p-type first region 10a is desirably not less than about 1×10¹⁸ atoms/cm³, and more desirably not less than about 1×10¹⁹ atoms/cm³.

In the embodiments illustrated in FIG. 1, five pn junctions were provided in the silicon substrate 10 between a total of six stacked layers (that is, six stacked p-type and n-type regions). The number of pn junctions provided in the silicon substrate 10 may be more than five. The total number of the p-type and the n-type regions to be stacked is, for example, in a range from 6 to 30 total regions. The number of pn junctions provided in the silicon substrate 10 is, for example, in a range from 5 to 29.

The number of pn junctions may be set according to the breakdown voltage required for the silicon substrate 10. For example, the number of pn junctions can be set to be smaller than the number obtained by dividing the breakdown voltage desired for the silicon substrate 10 by 10 V, and can be set to be larger than the number obtained by dividing the desired breakdown voltage by 20 V (that is, in a range between one tenth and one twentieth of the desired breakdown voltage). For example, when the breakdown voltage required for the silicon substrate 10 is 300 V, the number of pn junctions is set to be more than 15 and less than 30.

With the HEMT 100 according to the first aspect, it is possible to reduce the leak current between the silicon substrate 10 and the drain electrode 28 and to suppress the dielectric breakdown between the silicon substrate 10 and the drain electrode 28. According to the first aspect, an HEMT is provided in which the breakdown voltage can be improved between the silicon substrate and the electrode.

### Second Aspect

Some embodiments of a semiconductor substrate according to embodiment third aspect include a nitride semiconductor layer and a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer.

The semiconductor substrate according to the second aspect is the semiconductor substrate used in the semiconductor device according to the first aspect. Therefore, some descriptions of components of the semiconductor substrate according to the second aspect will be omitted, where such description would be duplicative of description provided above in reference to the semiconductor substrate used in the semiconductor device according to the first aspect.

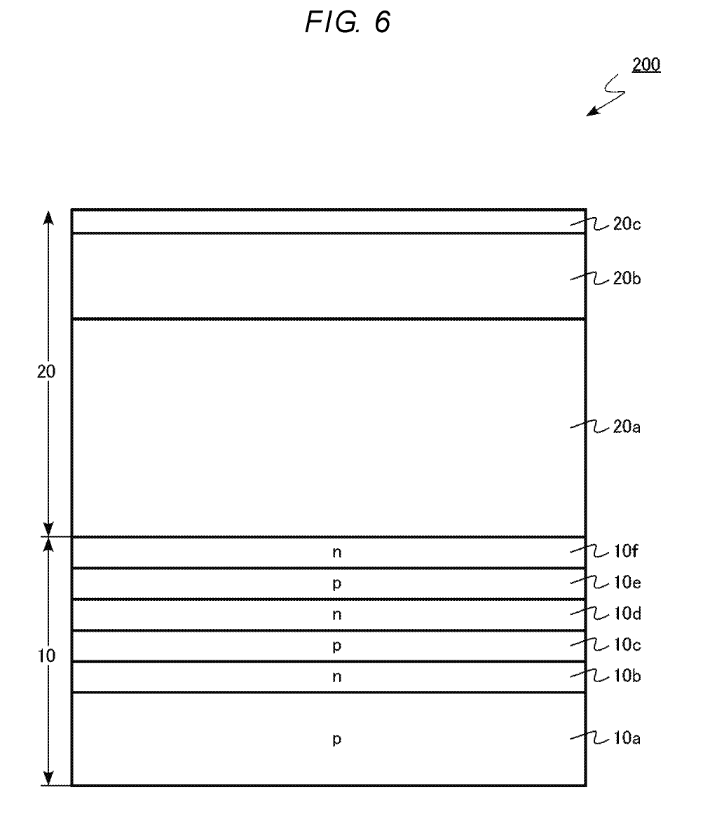

FIG. 6 is a schematic cross-sectional view of some embodiments of the semiconductor substrate according to the second aspect. As illustrated in FIG. 6, a semiconductor substrate 200 includes a silicon substrate 10 and a nitride semiconductor layer 20.

According to the semiconductor substrate 200 according to the second aspect, it is possible to manufacture an HEMT in which a breakdown voltage can be improved between the silicon substrate and an electrode.

### Third Aspect

Some embodiments of a semiconductor device according to a third aspect include: a nitride semiconductor layer; a silicon substrate including a p-type first region, an n-type second region provided between the first region and the nitride semiconductor layer, and a plurality of p-type third regions provided between the first region and the second region and being in contact with the first region; a first electrode, the nitride semiconductor layer being located between the silicon substrate and the first electrode; and a second electrode spaced apart from the first electrode, the nitride semiconductor layer being located between the silicon substrate and the second electrode.

The semiconductor device according to the third aspect is similar to that according to the first aspect except that the structure of the impurity region in the silicon substrate 10 is different. Therefore, some descriptions of components of the semiconductor substrate according to the third aspect will be omitted, where such description would be duplicative of description provided above in reference to the semiconductor device according to the first aspect.

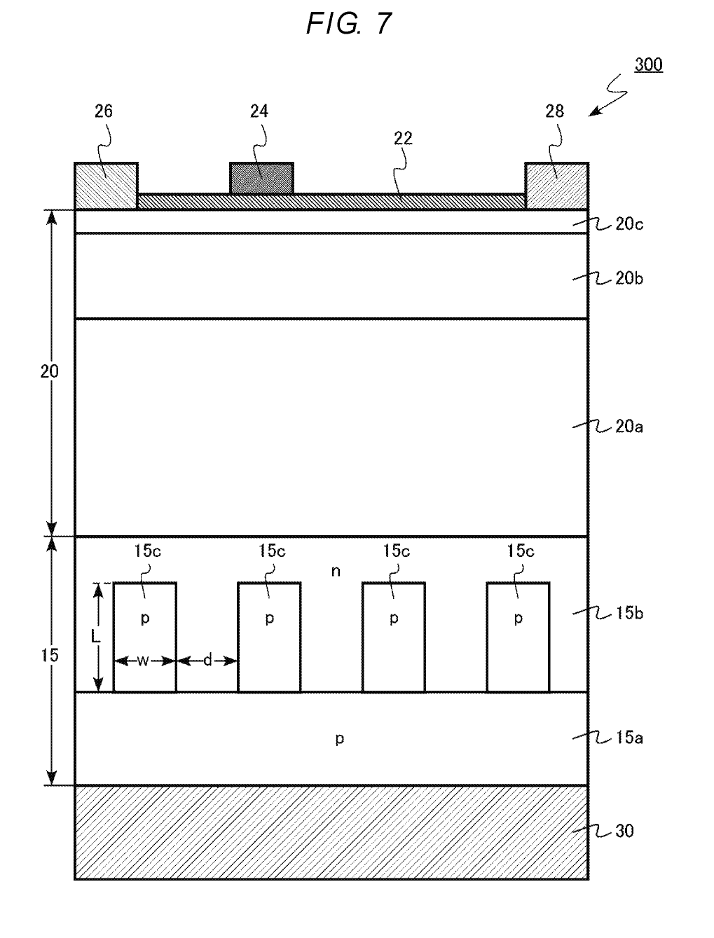

FIG. 7 is a schematic cross-sectional view of some embodiments of a semiconductor device according to the third aspect. The semiconductor device according to the third aspect is an HEMT using III-V compound semiconductors.

As illustrated in FIG. 7, an HEMT 300 semiconductor device includes a silicon substrate 15, a nitride semiconductor layer 20, a gate insulation layer 22, a gate electrode 24, a source electrode (first electrode) 26, a drain electrode (second electrode) 28, and a metal plate 30.

The silicon substrate 15 includes a p-type first region 15a, an n-type second region 15b, and a plurality of p-type third regions 15c.

The p-type first region 15a is in contact with the metal plate 30. The p-type first region 15a has a p-type impurity concentration of not less than about 1×10¹⁸ atoms/cm³ and not more than about 1×10²⁰ atoms/cm³, for example. For example, the p-type impurity concentration of the p-type first region 15a is higher than that of the p-type third region 15c.

The n-type second region 15b is provided between the p-type first region 15a and the nitride semiconductor layer 20. The n-type second region 15b has an n-type impurity concentration of not less than about 1×10¹⁴ atoms/cm³ and not more than about 1×10¹⁷ atoms/cm³, for example.

The plurality of p-type third regions 15c are provided between the p-type first region 15a and the n-type second region 15b. Each of the p-type third regions 15c is in contact with the p-type first region 15a. The p-type third regions 15c are spaced apart from the nitride semiconductor layer 20.

For example, the plurality of p-type third regions 15c are disposed in a transverse direction (horizontal direction in FIG. 7) at a constant pitch (equal to a sum of distances w and d shown in FIG. 7 and defined below). The p-type third regions 15c are contained or embedded in the n-type second region 15b. At least a portion of a surface of each respective p-type third region 15c may contact the p-type first region 15a.

The p-type third region 15c has a length (L in FIG. 7) of about 30 μm or longer and about 80 μm or shorter, for example.

The p-type third region 15c has a p-type impurity concentration of not less than about 1×10¹⁴ atoms/cm³ and not more than about 1×10¹⁷ atoms/cm³, for example.

Defining the n-type impurity concentration of a portion of the n-type second region 15b disposed between two p-type third regions 15c as Nn, and defining the width, the distance, and the p-type impurity concentration of the p-type third region 15c as w, d, and Np respectively, the following relation is satisfied, for example: 0.8≦(Nn×d)/(Np×w)≦1.2.

The p-type impurity concentration and the n-type impurity concentration in the silicon substrate 15 can be measured using, for example, SIMS. The p-type impurity concentration and the n-type impurity concentration are obtained using a value of a central portion in each of the impurity regions, for example. In addition, the length, the width, the distance, and the like of the p-type region and the n-type region in the silicon substrate 15 can be measured using, for example, SCM.

The silicon substrate 15 and the metal plate 30 are electrically connected to each other. For example, the silicon substrate 15 is grounded via the metal plate 30. In other words, a ground potential is applied to the silicon substrate 15 via the metal plate 30. In some embodiments, the p-type first region 15a is grounded. The p-type third regions 15c are also grounded via the p-type first region 15a. The n-type second region 15b is in a floating state.

The nitride semiconductor layer 20 is provided on the silicon substrate 15. The nitride semiconductor layer 20 includes a buffer layer 20a, a channel layer 20b, and a barrier layer 20c.

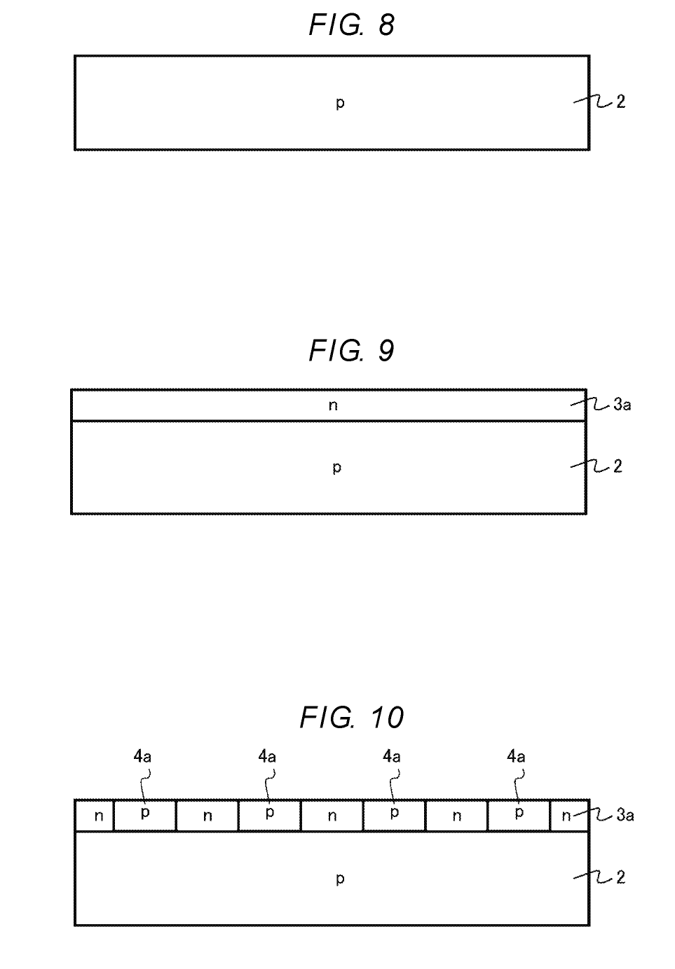

Some embodiments a first example method of manufacturing the semiconductor device according to the third aspect will be described below. FIGS. 8 to 14 are schematic cross-sectional views of steps of the first example method of manufacturing the semiconductor device according to the third aspect.

First, for example, a p-type silicon substrate 2 is prepared whose surface has a plane orientation of (111) (see FIG. 8) . The p-type silicon substrate 2 later becomes the p-type first region 15a.

Next, an n-type layer 3a is formed on the silicon substrate 2 through epitaxial growth (see FIG. 9). Subsequently, p-type regions 4a are formed by lithography and ion implantation (see FIG. 10). The p-type regions 4a may be alternately disposed with portions of the n-type layer 3a that constitute n-type regions.

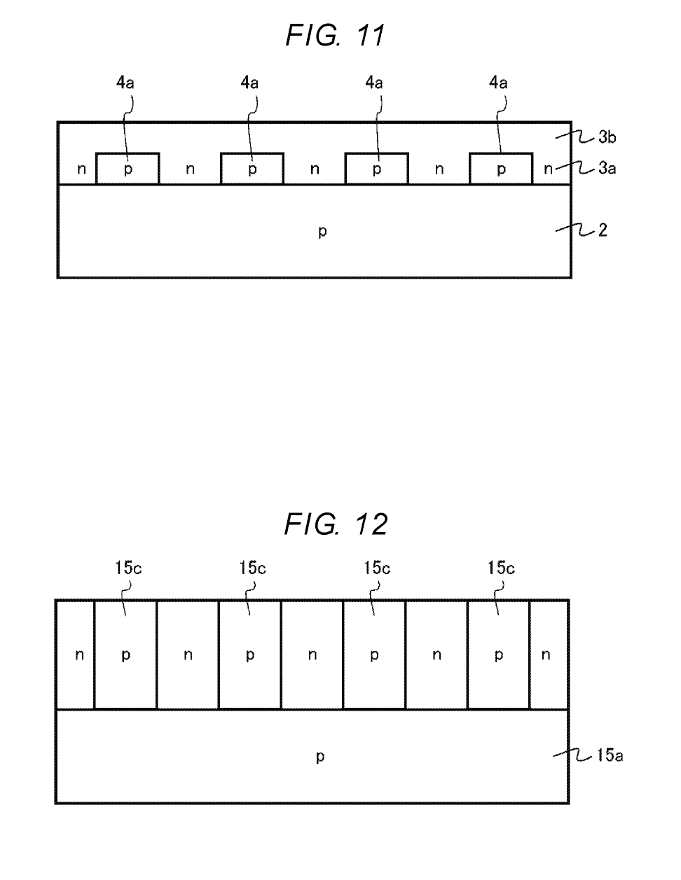

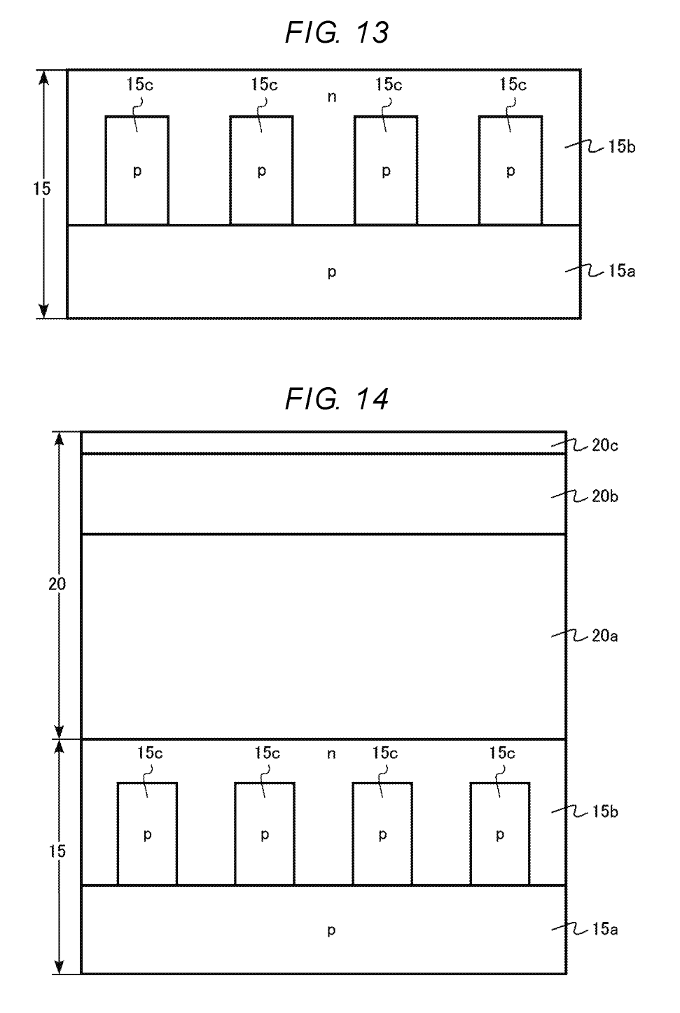

Next, an n-type layer 3b is formed on the n-type layer 3a and on the p-type regions 4a through epitaxial growth (see FIG. 11). P-type regions may be formed in the n-type layer 3b on the p-type regions 4a, such as by lithography and ion implantation. In this manner, and by repeating this process, the n-type region layer may be enlarged, and the p-type regions 4a may be enlarged to form the plurality of p-type third regions 15c (see FIG. 12). Subsequently, an n-type layer is formed on the plurality of p-type third regions 15c through epitaxial growth (see FIG. 13).

Next, for example, a buffer layer 20a, a channel layer 20b, and a barrier layer 20c are grown on the n-type second region 15b through epitaxial growth (see FIG. 14).

Thereafter, a gate insulation layer 22, a gate electrode 24, a source electrode 26, a drain electrode 28, a passivation layer (not illustrated), and the like are formed by any appropriate process.

Then, the silicon substrate 15 and the nitride semiconductor layer 20 are bonded onto the metal plate 30 by solder, whereby, manufacture of the HEMT 300 may be completed as illustrated in FIG. 7.

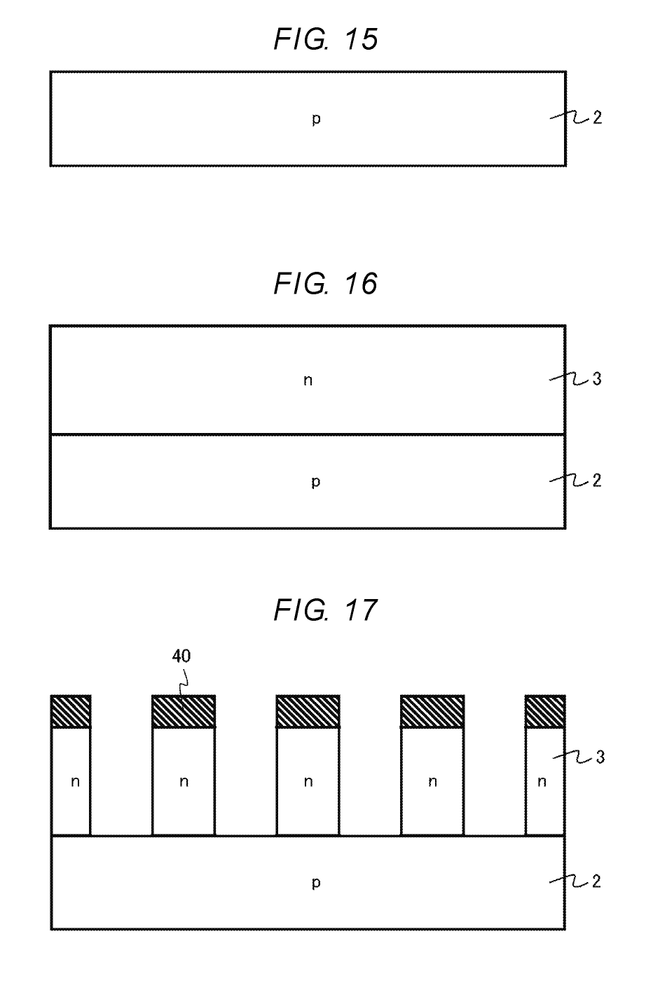

Some embodiments of a second example of a method of manufacturing the semiconductor device according to the third aspect will be described below. FIGS. 15 to 20 are schematic cross-sectional views of the second example of a method of manufacturing the semiconductor device according to the third aspect.

First, for example, a p-type silicon substrate 2 is prepared whose surface has a plane orientation of (111) (see FIG. 15). The p-type silicon substrate 2 later becomes the p-type first region 15a.

Next, an n-type layer 3 is formed on the silicon substrate 2 through epitaxial growth (see FIG. 16). Subsequently, a mask material 40 is formed by lithography and dry etching on the n-type layer 3. The mask material 40 is, for example, silicon oxide.

Subsequently, the n-type layer 3 is etched until the silicon substrate 2 is exposed by being subjected to dry etching, using the mask material 40 as a mask (see FIG. 17).

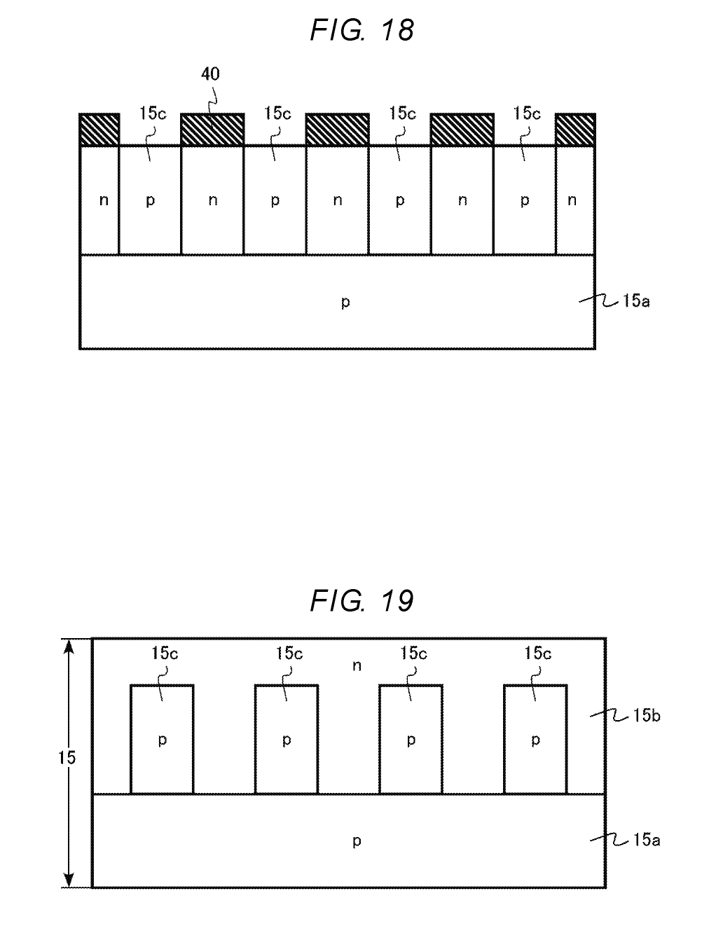

Subsequently, a plurality of p-type third region 15c are formed through selective epitaxial growth (see FIG. 18) on the p-type region 15a, between portions of the n-type layer 3. Next, the mask material 40 is removed by wet etching, and an n-type layer is formed on the plurality of p-type third regions 15c through epitaxial growth (see FIG. 19).

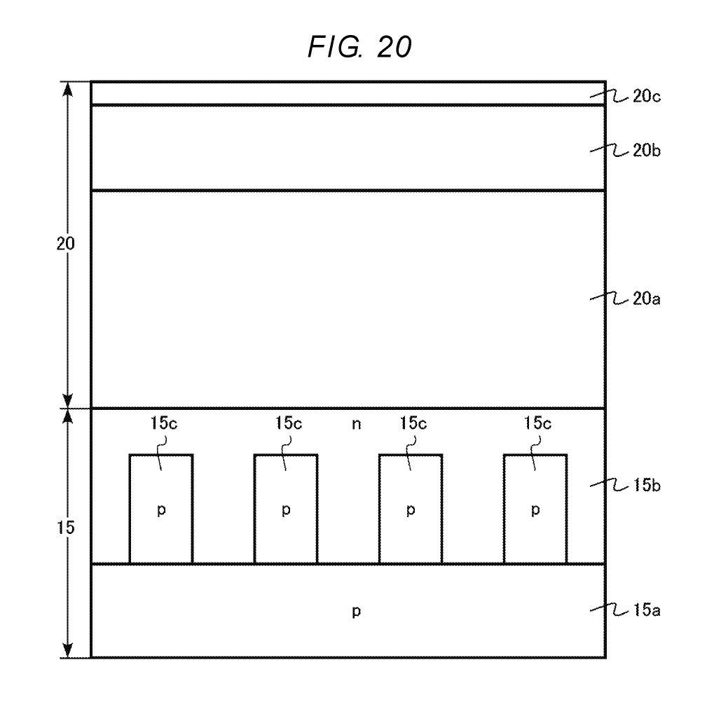

Next, for example, a buffer layer 20a, a channel layer 20b, and a barrier layer 20c are grown on the n-type second region 15b through epitaxial growth (see FIG. 20).

Thereafter, a gate insulation layer 22, a gate electrode 24, a source electrode 26, a drain electrode 28, a passivation layer (not illustrated), and the like are formed by a known process technique.

Then, the silicon substrate 15 and the nitride semiconductor layer 20 are bonded onto the metal plate 30 by solder, whereby, the manufacture of the HEMT 300 as illustrated in FIG. 7 is completed.

Some manners of operation and/or advantages of embodiments of the semiconductor device according to the third aspect will be described below.

In the HEMT 300 according to the third aspect, the silicon substrate 15 has a structure in which the p-type region and the n-type region are alternately disposed in a transverse direction (horizontal direction in the drawings). In other words, a plurality of pn junctions vertically extending in the silicon substrate 15 are formed side by side in the transverse direction.

When a high voltage is applied between the silicon substrate 15 and the drain electrode 28, a depletion layer spreads transversely into the p-type region and the n-type region, between which the pn junction is sandwiched, in the silicon substrate 15. For this reason, the electric field strength between the silicon substrate 15 and the drain electrode 28 is relaxed, and the breakdown voltage between the silicon substrate 15 and the drain electrode 28 is improved.

From the viewpoint of facilitating the spreading of the depletion layer into the p-type region and the n-type region, it is desirable that the impurity concentration of the p-type region and the n-type region be low. Accordingly, for example, the p-type impurity concentration of the p-type third region 15c is desirably not more than about 1×10¹⁷ atoms/cm³, and more desirably not more than about 1×10¹⁶ atoms/cm³. In addition, the n-type impurity concentration of the n-type second region 15b is desirably not more than about 1×10¹⁷ atoms/cm³, for example, and more desirably not more than about 1×10¹⁶ atoms/cm³.

From the viewpoint of improving the breakdown voltage by setting the disposition of the p-type region and the n-type region, it is desirable that the amount of acceptors contained in the p-type region be substantially equal to the amount of donors contained in the n-type region, the pn junction being sandwiched between the p-type region and the n-type region. Accordingly, defining the n-type impurity concentration of the n-type second region 15b held in the p-type third region 15c as Nn, and respectively defining the width, the distance, and the p-type impurity concentration of the p-type third region 15c as w, d, and Np, the following relation is desirable: 0.8≦(Nn×d)/(Np×w)≦1.2.

From the viewpoint of reducing the contact resistance between the silicon substrate 15 and the metal plate 30, it is desirable that the p-type impurity concentration of the p-type first region 15a be high. In addition, from the viewpoint of causing the p-type first region 15a to function as a field plate and improving current collapse characteristics of the HEMT 300, it is desirable that the p-type impurity concentration of the p-type first region 15a be high.

Accordingly, it is desirable that the p-type impurity concentration of the p-type first region 15a be higher than the p-type impurity concentration of each of the p-type third regions 15c. The p-type impurity concentration of the p-type first region 15a is desirably not less than about 1×10¹⁸ atoms/cm³, and more desirably not less than about 1×10¹⁹ atoms/cm³.

According to the HEMT 300 according to the third aspect, it is possible to reduce the leak current between the silicon substrate 15 and the drain electrode 28 and to suppress the dielectric breakdown between the silicon substrate 15 and the drain electrode 28. According to the third aspect, the HEMT is provided in which the breakdown voltage can be improved between the silicon substrate and the electrode.

As described herein, the first conductivity type is the p-type and the second conductivity type is the n-type, but the first conductivity type and the second conductivity type may alternatively be set to be the n-type and the p-type, respectively, for any of the embodiments described herein.

According to the first, second and third aspects, the gallium nitride or the aluminum gallium nitride is described herein as an example material of the nitride semiconductor layer. However, for example, indium gallium nitride, indium aluminum nitride, or indium aluminum gallium nitride containing indium (In) can additionally or alternatively be used. In addition, aluminum nitride can also be used as the material of the nitride semiconductor layer.

According to the first, second and third aspects, the undoped aluminum gallium nitride is described herein as an example material of the barrier layer 20c. However, for example, n-type aluminum gallium nitride can also be used.

According to the first, second and third aspects, the HEMT having a planar gate structure including the gate insulation layer is described herein as an example structure of the HEMT. However, embodiments of the present disclosure can also be implemented with an HEMT of another structure such as an HEMT of a junction gate structure having a p-type layer, an HEMT of a Schottky gate structure, or an HEMT of a recess gate structure having a gate electrode in a recess provided in a channel layer or a barrier layer. In addition, example embodiments of the present disclosure can be applied not only to the HEMT but also to diodes, for example.

In the description of some embodiments, a component provided “on” or “over” another component can encompass cases where the former component is directly on (e.g., in physical contact with) the latter component, as well as cases where one or more intervening components are located between the former component and the latter component.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure. Moreover, some or all of the above described embodiments can be combined when implemented.

What is claimed is:

1. A semiconductor device comprising:
a nitride semiconductor layer;
a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer;
a first electrode; and
a second electrode that is spaced from the first electrode;
wherein the nitride semiconductor layer is located between the silicon substrate and the first electrode, and the nitride semiconductor layer is located between the silicon substrate and the second electrode.

2. The semiconductor device according to claim 1, wherein the second region, the third region, the fourth region, the fifth region, and the sixth region are not in contact with the first electrode and the second electrode.

3. The semiconductor device according to claim 2, wherein the first region, the third region, and the fifth region of the first conductivity type have an impurity concentration of not less than 1×10¹⁴ atoms/cm³ and not more than 1×10¹⁷ atoms/cm³, and the second region, the fourth region, and the sixth region of the second conductivity type have an impurity concentration of not less than 1×10¹⁴ atoms/cm³ and not more than 1×10¹⁷ atoms/cm³.

4. The semiconductor device according to claim 3, wherein when the impurity concentration of the third region of the first conductivity type is defined as N3, a thickness of the third region is defined as t3, the impurity concentration of the fourth region of the second conductivity type is defined as N4, and a thickness of the fourth region is defined as t4, the following relation is satisfied:
0.8≦(N4×t4)/(N3×t3)≦1.2.

5. The semiconductor device according to claim 1, wherein the first region has a larger thickness than a thickness of any of the second region, the third region, the fourth region, the fifth region, and the sixth region.

6. The semiconductor device according to claim 1, wherein the first region of the first conductivity type has a higher impurity concentration than either of the third region of the first conductivity type and the fifth region of the first conductivity type.

7. A semiconductor substrate comprising:
a nitride semiconductor layer; and
a silicon substrate including a first region of a first conductivity type, a second region of a second conductivity type provided between the first region and the nitride semiconductor layer, a third region of the first conductivity type provided between the second region and the nitride semiconductor layer, a fourth region of the second conductivity type provided between the third region and the nitride semiconductor layer, a fifth region of the first conductivity type provided between the fourth region and the nitride semiconductor layer, and a sixth region of the second conductivity type provided between the fifth region and the nitride semiconductor layer.

8. A semiconductor device comprising:
a nitride semiconductor layer;
a silicon substrate including a p-type first region, an n-type second region provided between the first region and the nitride semiconductor layer, and a plurality of p-type third regions provided between the first region and the second region, each p-type third region in contact with the first region;
a first electrode; and
a second electrode spaced from the first electrode;
wherein the nitride semiconductor layer is located between the silicon substrate and the first electrode, and the nitride semiconductor layer is located between the silicon substrate and the second electrode.

9. The semiconductor device according to claim 8, wherein when an n-type impurity concentration of the second region held in the third regions is defined as Nn, and a width, a distance, and a p-type impurity concentration of the third region is defined as w, d, and Np, respectively, the following relation is satisfied:
0.8≦(Nn×d)/(Np×w)≦1.2.

10. The semiconductor device according to claim 9, wherein the first region has a higher p-type impurity concentration than does the third region.

11. The semiconductor device according to claim 8, wherein the first region has a higher p-type impurity concentration than does the third region.
